(19) United States
(12) Patent Application Publication
(10) Pub. No.: US 2025/0024588 A1
(43) Pub. Date: Jan. 16, 2025

(54) CABLE DEVICE AND METHOD OF PRODUCING THE SAME

(71) Applicant: Yamaichi Electronics Co., Ltd., Ota-ku, Tokyo (JP)

(72) Inventors: Takahiro SHIMOYAMA, Tokyo (JP); Akira YONEZAWA, Tokyo (JP); Hiroshi TAKAHIRA, Tokyo (JP)

(21) Appl. No.: 18/686,682

(22) PCT Filed: Oct. 5, 2021
(86) PCT No.: PCT/JP2021/036869

§ 371 Date: Sep. 27, 2024

(51) Int. Cl. H05K 1/02; H01B 7/08; H01B 13/00

(52) U.S. Cl. CPC H05K 1/0245; H01B 7/0892; H01B 13/0036; H05K 1/0277

(57) ABSTRACT

Cable device (9) includes a flexible cable (2) including a plurality of cable-strips (35) formed in accordance with one or more slits (21), and one or more bundling members (5) for bundling the plurality of cable-strips (35) into a stacked state. The plurality of cable-strips (35) includes two or more signal transmission strips (35s) each of which includes at least one high-frequency signal transmission line. The cable device (9) further includes a spacer (80) interposed between the signal transmission strips (35s) in a stacking direction of the cable-strips (35) in at least one or more bundling locations by the one or more bundling members (5).

### TECHNICAL FIELD

The present disclosure is related to a cable device for HF (high-frequency) signal transmission and a method of producing the same.

### BACKGROUND ART

As disclosed in PTL 1, it has been known to bundle flexible wiring fins formed by slits through a flexible wiring board. This allows enhanced freedom of deformation of the flexible wiring board. PTLs 2 and 3 disclose a similar type of device as PTL 1.

PTL 4 discloses that a spacer is interposed between 1^{st} and 2^{nd} flexible substrates to enable characteristic impedance matching with a characteristic impedance between a tester and a probe needle. PTL 5 discloses that a spacer is arranged such that a distance between wiring patterns opposing at a bending location of a print wiring board is maintained at a certain distance or more.

### CITATION LIST

### Patent literature

[PTL 1] Japanese patent application laid-open No. 2011-66086

[PTL 2] Japanese patent application laid-open No.2010-40929

[PTL 3] Japanese patent No. 4215775

[PTL 4] Japanese patent application laid-open No.2008-210839

[PTL 5] Japanese patent application laid-open No.2010-153540

### SUMMARY

### Technical Problem

This is a need to bundle, by a bundling member, plural cable-strips which are sectioned by one or more slits (normally plural slits) in a flexible cable such as FPC (Flexible Printed Circuit) or FFC (Flexible Flat Cable). However, there is a possibility that, if the plural cable-strips were bundled by a bundling member following the PTLs 1-3, a desired transmission characteristic of HF signal in a flexible cable might not be obtained due to capacitance coupling between HF signal transmission line of one cable-strip and HF signal transmission line of another cable-strip.

### Solution to Problem

Cable device according to one aspect of the present disclosure includes: a flexible cable including a plurality of cable-strips formed in accordance with one or more slits, the plurality of cable-strips including two or more signal transmission strips each of which includes at least one high-frequency signal transmission line; one or more bundling members for bundling the plurality of cable-strips into a stacked state; and a spacer interposed between the signal transmission strips in a stacking direction of the cable-strips in at least one or more bundling locations by the one or more bundling members. The spacers may be separate from the bundling members. The spacers may include a dummy strip of the flexible cable.

A cable device according to another aspect of the present disclosure includes a flexible cable including a plurality of cable-strips formed in accordance with one or more slits, the plurality of cable-strips including two or more signal transmission strips each of which includes at least one high-frequency signal transmission line; and one or more spacer-strips which can be interposed between the signal transmission strips in a stacking direction of the cable-strips in one or more bundling locations where the plurality of cable-strips are bundled into a stacked state. The spacers may be separate from the bundling members.

A method of producing a cable device according to yet another aspect of the present disclosure includes: producing or preparing a flexible cable including a plurality of cable-strips formed in accordance with one or more slits, the plurality of cable-strips including two or more signal transmission strips each of which includes at least one high-frequency signal transmission line; bundling the plurality of cable-strips into a stacked state by one or more bundling members; and inserting a spacer between the signal transmission strips in a stacking direction of the cable-strips at least in one or more bundling locations by the one or more bundling members.

In some embodiments, the high-frequency signal transmission line includes one or more signal lines formed on a first surface of a dielectric layer, and a ground layer formed on a second surface of the dielectric layer; and the spacer is stacked (selectively) onto the signal transmission strip on the side of the second surface on the same side as the ground layer. In some cases where an adhesive is used, the spacer is stacked onto the signal transmission strip via the adhesive on the side of the second surface on the same side as the ground layer, and the spacer is not stacked onto the signal transmission strip via the adhesive on the side of the first surface on the same side as the signal lines. In some cases, the adhesive may be formed to overlap at least the ground layer (e.g. a partial or entire region of the ground layer) on the side of the second surface on the same side as the ground layer. Accordingly, efficient stacking of spacer and reduced influence of a relative permittivity of the adhesive owing to the ground layer may be simultaneously achieved.

In some embodiments, the spacer includes one or more spacer-strips. The spacer-strips may be stacked at least onto the signal transmission strips. In cases where the spacer include two or more spacer-strips, the signal transmission strip of single layer and the spacer-strip of single layer may be alternately stacked in the stacking direction of the cable-strips in the one or more bundling locations.

In some embodiments, the plurality of cable-strips includes at least one dummy strip in addition to the two or more signal transmission strips, the dummy strip including no high-frequency signal transmission line. The at least one dummy strip is located at an outermost layer in the stacking direction of the plurality of cable-strips at least in the one or more bundling locations by the one or more bundling members. Additionally or alternatively, the dummy strip is used as the above-noted spacer or the spacer-strip.

In some embodiments, each of the two or more signal transmission strips includes: a dielectric layer; one or more differential signal lines formed on a first surface of the dielectric layer; at least a pair of ground lines formed on the first surface of the dielectric layer so as to sandwich the one or more differential signal lines at both sides thereof; a ground layer formed on a second surface of the dielectric layer; and at least a pair of through-electrodes that connect the respective ground lines of the at least a pair of ground lines to the ground layer.

In some embodiments, the slit formed in the flexible cable has a first slit end closer to a first end of the flexible cable and a second slit end closer to a second end of the flexible cable, and a length of the spacer-strip is equal to or greater than a half of a length of the slit between the first and second slit ends, preferably equal to or greater than 70% or 80% or 90% of the length or equivalent to or longer than the length. Equivalent length indicates a length that is in 0.95 to 1.05 times a given length.

In some embodiments, a relative permittivity of the spacer is 2 or less; and/or a thickness of the spacer is 0.1 mm or more; and/or a material of the spacer is a non-woven fabric or cloth or paper.

In some embodiments, the one or more bundling members each is a tubular member (e.g. a spiral tube or a braided tube with slit) encapsulating a laminate including the cable-strips and the spacer.

In some embodiments, the plurality of cable-strips are bundled by the bundling members for each subset of the plurality of cable-strips. The subsets may be defined based on a direction of transmitted signal.

### Advantageous Effects of Invention

According to an aspect of the present disclosure, degradation of a transmission characteristic of high-frequency signal in a flexible cable may be suppressed or avoided even if plural cable-strips are bundled by a bundling member.

### BRIEF DESCRIPTION OF DRAWINGS

FIG. 1 is a schematic perspective view of HF signal transmission device according to an aspect of the present disclosure in which plug members secured at both ends of FPC are connected to connectors mounted on wiring boards respectively.

FIG. 2 is a schematic top view of FPC with the plug members attached thereto.

FIG. 3 is a schematic partial cross section of a laminate including a FPC and a spacer, wherein slits slitting the laminate in its thickness direction are formed between adjacent FPC-strips.

FIG. 4 is a schematic partial enlarged view of one end of FPC in which contacts are aligned in width direction of the FPC.

FIG. 5 is a schematic cross section of cable device taken along alternate long and short dash lines X-X in FIG. 1 in which FPC-strips and spacer-strips are alternately laminated in a state where the FPC-strips are bundled by a bundling member.

FIG. 6 is a schematic view of one embodiment of the spacer.

FIG. 7 is a schematic view of another embodiment of the spacer.

FIG. 8 is a schematic view of yet another embodiment of the spacer.

FIG. 9 is a schematic perspective view of HF signal transmission device in which bundling member and spacer are omitted compared with FIG. 1.

FIG. 10 is a chart showing fluctuation in insertion loss regarding frequency of the cable device according to the present disclosure.

FIG. 11 is a chart showing fluctuation in return loss regarding frequency of the cable device according to the present disclosure.

FIG. 12 is a chart showing fluctuation in insertion loss regarding frequency of the cable device depicted in FIG. 9.

FIG. 13 is a chart showing fluctuation in return loss regarding frequency of the cable device depicted in FIG. 9.

FIG. 14 is a chart showing fluctuation in insertion loss regarding frequency in a situation where FPC-strips are bundled by binging member in FIG. 9.

FIG. 15 is a chart showing fluctuation in return loss regarding frequency in a situation where FPC-strips are bundled by binging member in FIG. 9.

FIG. 16 is a schematic cross section of a laminate of the FPC-strip with spacer-strips stacked onto its both sides.

FIG. 17 is a schematic view showing a variation regarding stacking of the spacer onto the FPC.

FIG. 18 is a chart showing a measurement of insertion loss regarding FIG. 16.

FIG. 19 is a chart showing a measurement of return loss regarding FIG. 16.

FIG. 20 is a schematic diagram for illustration of production method according to the present disclosure.

FIG. 21 is a schematic cross section of a cable device in which a dummy strip is included in the cable-strips and is located at the uppermost layer of the laminate at a bundling location by the bundling member.

FIG. 22 is a schematic cross section of a cable device in which dummy strips are used as the spacer-strips.

FIG. 23 is a schematic view showing a variation in which a spacer is integrally provided with the bundling member (i.e. the bundling member encompasses the spacer).

### DESCRIPTION OF EMBODIMENTS

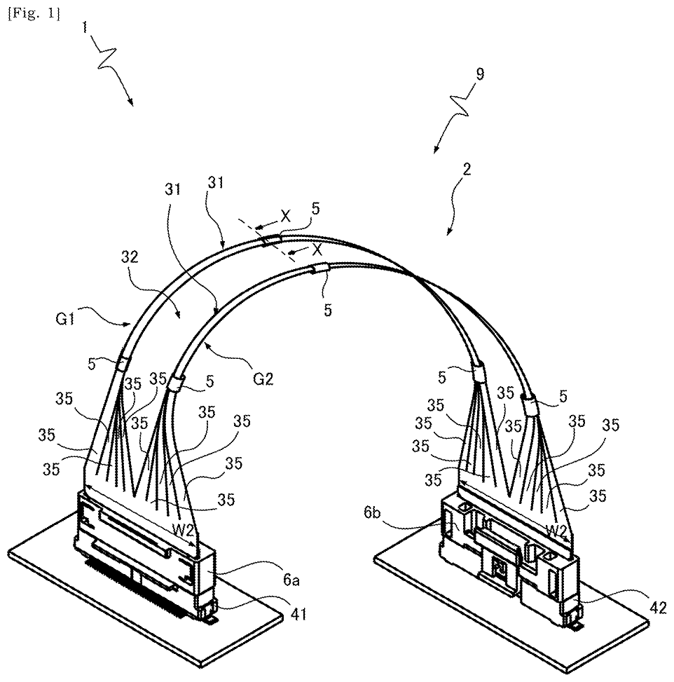

Hereinafter, various embodiments and features would be discussed with reference to FIGS. 1-23. A skilled person would be able to combine respective embodiments and/or respective features without requiring excess descriptions, and would appreciate synergistic effects of such combinations. Overlapping descriptions among the embodiments are basically omitted. Referenced drawings aim mainly for describing inventions and are simplified for the sake of convenience of preparation of drawings. The respective features should be appreciated as universal features not only effective to cable devices and methods of producing the same presently disclosed but also effective to other various cable devices and methods of producing the same not disclosed in the present specification.

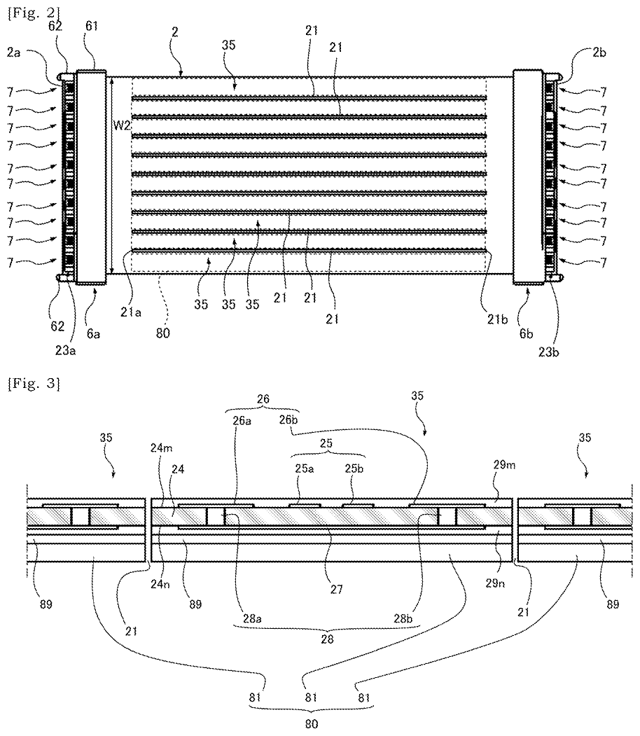

As depicted in FIG. 1, a HF (high-frequency) signal transmission device 1 has a cable device 9, and first and second connectors 41 and 42. The cable device 9 has a FPC 2, bundling members 5, and spacers 80 described below. The FPC 2 is a non-limiting example of flexible cable, and may be a FFC (Flexible Flat Cable) instead of a FPC (Flexible Printed Circuit). Plural FPC-strips (cable-strips) 35 are formed in the FPC 2 in accordance with slits 21 (see FIGS. 2 and 3 together). Two or more FPC-strips 35 are bundled by the bundling member(s) 5. This enables the FPC 2 to have a reduced width than a width W2 (a width between both edges) in a non-bundled condition. Such bundling of the FPC-strips 35 in the cable device 9 facilitates, for example, increased efficiency of cooling inside an apparatus in which the HF signal transmission device 1 is incorporated (hereinafter referred to just as an apparatus) or increased freedom in wiring design inside the apparatus or increased efficiency in assembling the apparatus (such as routing and connecting of cables or the like).

The FPC-strips 35 may be bundled by the bundling members 5 for each subset of the FPC-strips 35. The subsets of the FPC-strips 35 may be defined based on a direction of transmitted HF signal. For example, as understood from FIG. 1, a first subset G1 may be associated with a first direction (upstream direction) of signal transmission, and a second subset G2 may be associated with a second direction (downstream direction) of signal transmission. The second direction is opposite to the first direction. This would suppress a crosstalk between HF signals propagating in different directions.

The number of subsets of the FPC-strips 35 may necessarily be 2 or more but, as long as this condition is satisfied, other number such as 3 or 4 may be adoptable. Increased number of subsets results in increased number of bundling members 5 but increase of cost would be avoided or suppressed by using a versatile bundling member 5 (e.g. spiral tube or braided tube with slit). The FPC 2 has plural bundled portion 31 corresponding to its subsets, with space(s) 32 formed therebetween. The bundled portion 31 is in an arc-like curbed condition.

Number of the bundling members 5 attached per a subset of the FPC-strips 35 may be 1 or more and in some cases 2 or more, allowing the bundled portion 31 to be formed sufficiently longer and uniformly. Note that the bundled portion 31 has a flexibility likewise the FPC 2 and the FPC-strips 35. Thus, the bundled portion 31 could be flexed in an extent that does not pose any influence onto the transmission characteristic of HF signal in the cable device 9 or in an extent that pose ignorable influence thereto.

In the depicted example, ten FPC-strips 35 are included in the FPC 2. The FPC-strips 35 are bundled by the bundling members 5 for each subset of 5 strips. Three bundling members 5 are attached per each subset. In a situation where the ten FPC-strips 35 were bundled as a set by the bundling member 5, the degree of flexure cased in the FPC-strip 35 would differ depending on the position of FPC-strip 35 in the width direction of FPC 2. Imparting a higher flexibility to the FPC 2 may be required due to the largely flexing FPC-strips 35. Such problem would be avoided or suppressed by bundling the FPC-strips 35 by the bundling members 5 for each subset as discussed above. It should be noted that, if the number of the FPC-strips 35 is not large (e.g. the total number of the FPC-strips 35 is 8 or less or 6 or less), the FPC-strips 35 may be bundled by the bundling members 5 in total as a set rather than for each subset.

The FPC 2 is a belt-like member extending in a given direction with a given width W2, and has first end 2a and second end 2b opposite to the first end 2a in its elongation direction (see FIG. 2). The FPC 2 is typically a belt-like member elongated in the above-noted given direction, but should not be limited to this. The FPC 2 has HF signal transmission lines 7 which are arranged in its width direction. The slits 21 are formed between adjacent transmission lines 7 in the width direction of the FPC 2, thereby forming the FPC-strips 35 in the FPC 2.

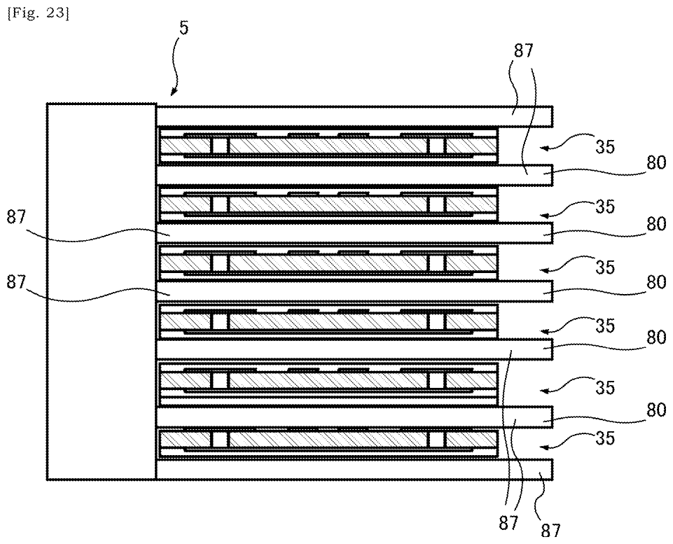

The FPC-strip 35 is a strip extending in the given direction which is the same as the elongation direction of the FPC 2, and has a flexibility similar to the FPC 2. The FPC-strip 35 is (typically) provided with one channel of transmission line 7 but may be provided with plural channels of transmission lines 7. Additionally or alternatively, line(s) (power line, signal line, control line, test line or the like) other than the HF transmission line may be provided. Each width of the FPC-strip 35 is substantially the same, but should not be limited to this. By equally setting the widths of the FPC-strips 35, it may be possible to more easily bundle the FPC-strips 35 by the bundling members 5. Note that, in the present specification, the FPC-strip 35 indicates a signal transmission strip in which a HF signal transmission line is provided except for the paragraphs related to or referring to any one of FIGS. 21 and 22.

The slit 21 extends in the same direction as the elongation direction of the FPC 2, and has a first slit end 21a closer to the first end 2a of the FPC 2 and a second slit end 21b closer to the second end 2b of the FPC 2. As a result of this, the FPC 2 has a first end portion 23a (with no slit) formed between the first end 2a and the first slit ends 21a of the slits 21, and a second end portion 23b (with no slit) formed between the second end 2b and the second slit ends 21b of the slits 21. Also, the first and second end portions 23a, 23b are portions to which the respective FPC-strips 35 are coupled.

The FPC 2 and each FPC-strip 35 include a dielectric layer 24, signal lines 25 formed on a first surface 24m of the dielectric layer 24, and a ground layer 27 formed on a second surface 24n of the dielectric layer 24, i.e. the transmission line 7 includes a microstrip line (see FIG. 3). The slits 21 are formed between the transmission lines 7 as discussed above, thus enhancing an insulating characteristic between the transmission lines 7 and enabling the bundling of the FPC-strips 35. The signal line 25 may include a pair of signal lines 25a and 25b used as a differential signal transmission line. The signal lines 25a,25b extend in parallel one another with a given interspace. The ground layer 27 may cover the second surface 24n of the dielectric layer 24 in the entire width of the FPC-strip 35.

In some cases, the respective ground layers 27 of the adjacent FPC-strips 35 are not electrically connected one another on the FPC 2. The width of the ground layer 27 is lesser than the width of the FPC-strip 35, and the ground layer 27 is not slit by the slit 21. Furthermore, a portion of the second cover layer 29n is formed between the ground layer 27 and the slit 21. This allows increased isolation and reduced crosstalk between the adjacent transmission lines 7. Note that, the transmission lines 7 are arranged in the stacking direction of the FPC-strips 35 in the bundled portion 31 of the FPC 2, but they are arranged in the width direction of FPC 2 in the first and second end portions 23a and 23b, thus suppression of crosstalk would be facilitated also in the situation where the bundling members 5 are used.

The FPC 2 and each FPC-strip 35 may include at least a pair of ground lines 26 to sandwich the signal lines 25 at the both sides thereof on the first surface 24m of the dielectric layer 24; that is, the transmission line 7 includes a coplanar line additionally to the above-noted microstrip line (i.e. it could be said that the transmission line 7 is based on both of the microstrip line and the coplanar line).

The FPC 2 and each FPC-strip 35 further includes at least a pair of through-electrodes 28 which connect, to the ground layer 27, the ground lines 26 of the at least a pair of ground lines 26 respectively. The signal line 25 is surrounded by a ground potential, thus effecting EMI (Electro Magnetic Interference) measures and facilitating the transmission of HF signal with lesser loss.

Note that, the ground line 26a extends in parallel with the signal line 25a with a given distance and similarly, the ground line 26b extends in parallel with the signal line 25b with a given distance. The first ground line 26a is electrically connected to the ground layer 27 via the through-electrode 28a. The second the ground line 26b is electrically connected to the ground layer 27 via the through-electrode 28b.

The FPC 2 and each FPC-strip 35 may further include a first cover layer 29m formed on the first surface 24m of the dielectric layer 24 to cover the signal line 25 (e.g. the differential signal line) and a second cover layer 29n formed on the second surface 24n of the dielectric layer 24 to cover the ground layer 27 for one or more objects (e.g. Fire resistance, mechanical strength, prevention of short circuit). One or both of them may be omitted. The cover layer is made of polyimide, polyethylene terephthalate or the like, for example.

The contacts of the transmission lines 7 (e.g. the contacts of the signal line 25, the ground line 26, and the ground layer 27) are formed on the first and second end portions 23a,23b of the FPC 2 (see FIGS. 2 and 4). For example, the signal lines 25 and the ground lines 26 are not covered by the first cover layer 29m in the first and second end portions 23a,23b of the FPC 2 such that their contacts are exposed. In the depicted example, the contacts 25c,25d of the signal lines 25a,25b are sandwiched between the contacts 26c,26d of the ground lines 26a,26b.

The FPC 2 may be produced based on a bump-build-up method in some cases. In the bump build-up method, a large number of bumps are formed on a first surface of a first metal foil, and a dielectric layer (e.g. liquid crystalline polymer) and second metal foil are stacked in this order onto the first surface of the first metal foil on which the bumps have been formed. This is followed by thermal pressing to bring the first metal foil, the dielectric layer, and the second metal foil into intimate contact. In this laminate, the first and second metal foils are electrically connected one another via the through-electrodes originating from the bumps. The first metal foil is used for the ground layer 27, and the second metal foil is used for the signal and ground lines 25 and 26. Patterning of metal foil (e.g. selective etching) allows formation of the signal and ground lines. Note that the first and second metal foils are copper foils. In another case, the FPC 2 may be produced by hole-formation through a double-sided copper clad laminate (e.g. hole-formation using drill or laser), plating of copper inside through-holes (e.g. electroless plating) and etching. Other production methods may be adoptable.

The dielectric layer 24 has a given relative permittivity and is made of liquid crystalline polymer, polyimide, polyphenylene sulfide, polyethylene terephthalate, polyvinylidene chloride, or polypropylene, for example. The signal line 25, the ground line 26, and the ground layer 27 are made of metal such as copper (e.g. copper foil such as a rolled copper foil or electrolytic copper foil), aluminum (e.g. aluminum foil) or the like. The through-electrodes 28 may be made of the same metal as ones of the signal line 25, the ground line 26, and the ground layer 27.

The cable device 9 may further has a first plug member 6a secured at the first end portion 23a of the FPC 2, and a second plug member 6b secured at the second end portion 23b of the FPC 2 (see FIG. 2). The first plug member 6a has a body 61 and alignment protrusions 62 each protruding from the body 61; and the contacts of the transmission lines 7 are arranged between the alignment protrusions 62. The second plug member 6b is configured similar to the first plug member 6a. The alignment protrusions 62 of the first plug member 6a are inserted into slots (not-depicted) of the first connector 41, allowing that the contacts of the transmission lines 7 of the FPC 2 are precisely aligned to the contacts of the first connector 41. The same description applies to the second plug member 6b.

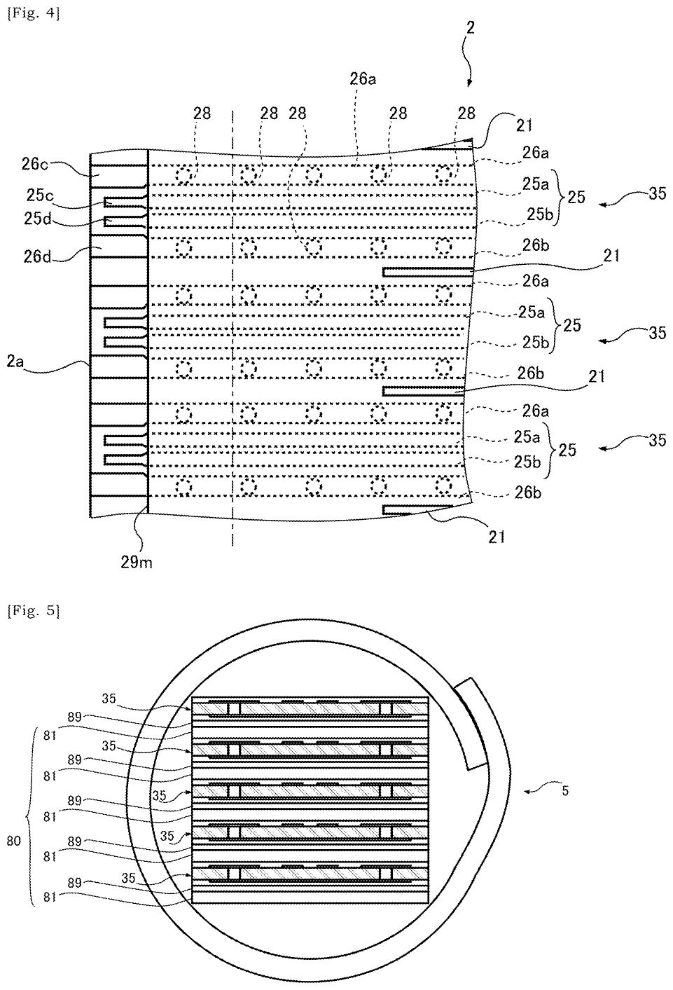

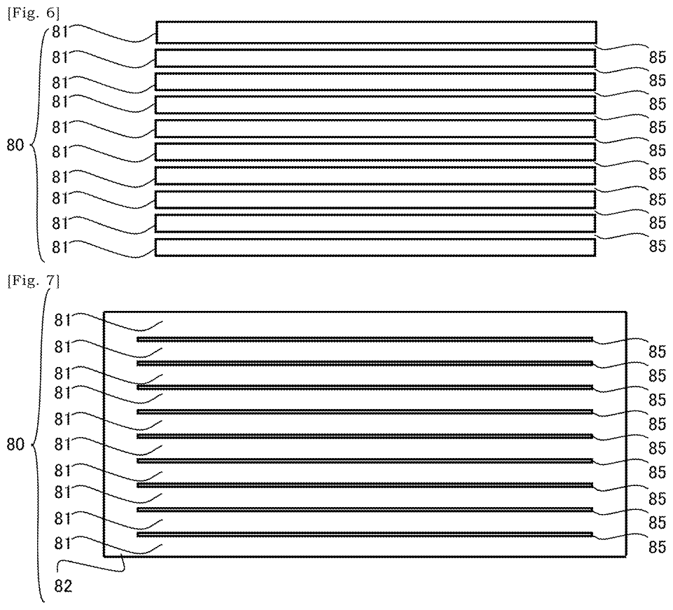

In the present embodiment, the cable device 9 has a spacer 80 inserted between the FPC-strips 35 (signal transmission strips) in the stacking direction of the FPC-strips 35 in one or more bundling locations by at least one or more bundling members 5 (see FIG. 5). The distance between the FPC-strips 35 is reduced in the locations where the FPC-strips 35 are bundled by the bundling member 5 as force is applied from the bundling member 5 to the laminate of the FPC-strips 35. In this situation, the influence of parasitic capacity caused between the FPC-strips 35 becomes no longer ignorable, and the transmission characteristic of HF signal in the FPC 2 may possibly be degraded. In the present disclosure, the spacer 80 is employed at least in the bundling location of the FPC-strips 35 by the bundling member 5, thus avoiding or suppressing the occurrence of such problem.

A binding band, a thread, a tape, a tubular member or the like may be used for the bundling member 5 but, the tubular member is preferred among the options. In some cases, the bundling member 5 may be a tubular member, such as a spiral tube or a braided tube with slit, which surrounds the laminate including the FPC-strips 35 and the spacer 80. Use of the tubular member allows a reduced possibility of excessively large force applied from the bundling member 5 to the FPC-strips 35. The spacer 80 may be compressed due to externally applied force regardless of its material. If the spacer 80 were compressed, the distance between the FPC-strips 35 would be reduced and the influence of parasitic capacity would be greater. The use of the tubular bundling member 5 allows that the elicitation of such problem is avoided or suppressed. From a viewpoint of efficiency of manufacturing or assembling of the cable device 9, a spacer 80 may be stacked onto the FPC 2. The spacer 80 may include one or more spacer-strips 81 stacked onto at least the FPC-strips 35 (signal transmission strips). The spacer-strip 81 may be interposed between the FPC-strips 35 in the stacking direction of the FPC-strips 35 in one or more bundling locations where the FPC-strips 35 are bundled into the stacked state.

The spacer-strip 81 may be a belt-like portion extending in a given direction likewise the FPC-strip 35. When two or more spacer-strips 81 are provided, the respective spacer-strips 81 may have a substantially same width, but should not be limited to this. When the width of the spacer-strip 81 is set to be equal to the width of the FPC-strip 35, it would be avoided or suppressed that the bundling of the FPC-strips 35 by the bundling member 5 is hindered by the spacer-strips 81.

The number of the spacer-strips 81 may be equal to or one less than the number of the FPC-strips 35. For example, when total two FPC-strips 35 were in the FPC 2, a required number of the spacer-strips 81 to be interposed between the FPC-strips 35 would be one but, it would be possible to stack the spacer-strips 81 to the FPC-strips 35 respectively. By stacking the spacer-strip 81 to the FPC-strip 35 as such in a relationship of one by one, it would be possible to cancel a restriction regarding the order of stacking of the FPC-strips 35.

The length of the spacer-strip 81 may preferably be a half or more, 70% or more, 80% or more, or 90% or more of the length of the slit 21 ranging between the first and second slit ends 21a, 21b of the slit 21, and more preferably it may be substantially equal to or longer than the length of the slit 21. This allows that a given distance corresponding to the thickness of the spacer-strip 81 is more reliably secured between the FPC-strips 35, suppressing the fluctuation of the parasitic capacity.

The relative permittivity of the spacer 80 and/or the spacer-strip 81 may be 2 or less. Additionally or alternatively, the thickness of the spacer 80 and/or the spacer-strip 81 may be 0.1 mm or more. Preferably, the spacer 80 and/or the spacer-strip 81 has a flexibility or deformability which does not hinder the flexibility of the flexible cable, and is made of soft porous material such as a non-woven fabric. This allows that both conditions of the relative permittivity and the thickness are satisfied easily and at a lower cost. Note that it would be possible to use a cloth or paper for the spacer 80 and/or the spacer-strip 81.

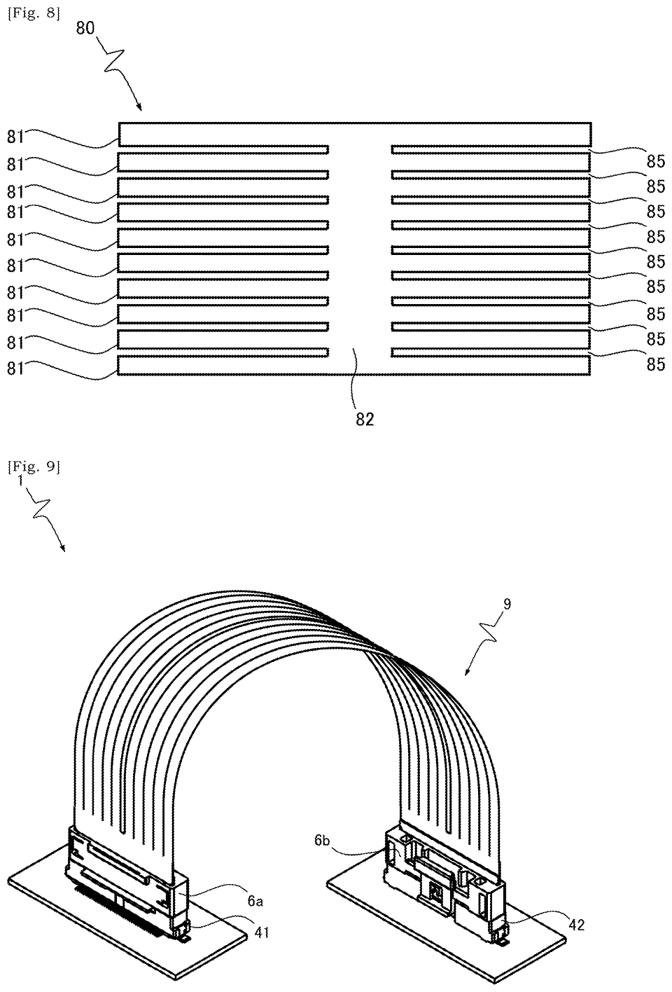

The spacer 80 may take a configuration of completely separate distinct spacer-strips 81 as depicted in FIG. 6 or a configuration where the spacer-strips 81 are interconnected one another via an interconnection portion 82 as depicted in FIG. 7. The interconnection portion 82 may be stacked onto the first end portion 23a or the second end portion 23b of the FPC 2 but could be arranged on other locations. For example, in a case depicted in FIG. 8, the interconnection portion 82 is arranged to transverse and interconnect the spacer-strips 81. In either configuration, the slits 85 are formed between the spacer-strips 81 when the FPC-strips 35 are not bundled by the bundling member 5. Preferably, the spacer 80 is stacked onto the FPC 2 and then cut into the spacer-strips 81, thereby reducing the burden of respectively stacking the spacer-strips 81 to the FPC-strips 35.

The spacer 80 and/or the spacer-strips 81 may be stacked onto the FPC-strips 35 via an adhesive and may adhere thereto. In this situation, laminating of the FPC-strips 35 automatically allows the spacer-strips 81 to be interposed between the FPC-strips 35, enhancing the efficiency of manufacturing or assembling of the cable device 9. The adhesive layer 89 is clearly depicted as a layer in FIGS. 3 and 5 but, embodiments are envisioned where the adhesive layer 89 is not formed in a form of layer or is not observable as a layer. For example, in a case where the spacer-strip 81 is a non-woven fabric, the adhesive permeates the non-woven fabric and it would be difficult to observe it as the adhesive layer 89. It would be possible to employ other approaches such as thermal compression bonding, heat welding, ultrasonic welding or the like without the use of adhesive.

In some cases, the FPC-strips 35 of single layer and the spacer-strips 81 of single layer are alternately stacked in the stacking direction of the FPC-strips 35 in the bundling location of the FPC-strips 35 by the bundling member 5. This may be a result of stacking of the spacer-strips 81 of single layer onto one side of the FPC-strips 35. Increase in the thickness of the laminate of the FPC-strips 35 and the spacer-strips 81 depicted in FIG. 5 may be suppressed. In cases where the spacer-strips 81 are stacked onto and adhere to the FPC-strips 35 via adhesive, a volume of adhesive layer may be reduced and an influence may be suppressed otherwise imparted to the transmission characteristic of HF signal in the cable device 9 due to the relative permittivity of the adhesive layer.

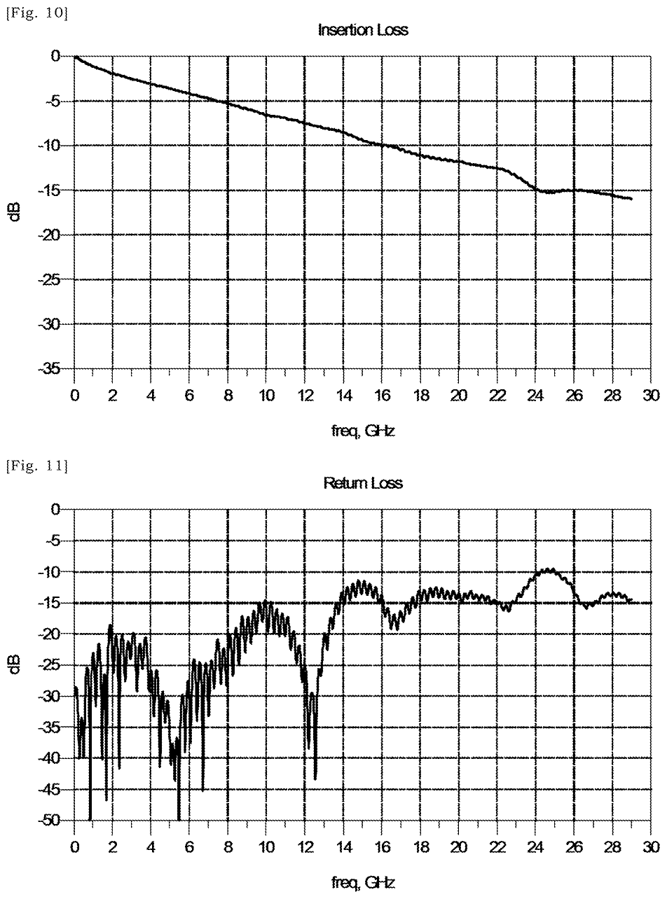

The spacer 80 and/or the spacer-strip 81 may be stacked (e.g. via adhesive) selectively onto the FPC 2 or the FPC-strips 35 at the side of the second surface 24n of the dielectric layer 24 which is on the same side as the ground layer 27. That is, the spacer 80 and/or the spacer-strip 81 is stacked onto the FPC 2 or the FPC-strip 35 only on the side of the second surface 24n of the dielectric layer 24, and is not stacked onto the FPC 2 or the FPC-strip 35 on the side of the first surface 24m of the dielectric layer 24. When the adhesive is used in the laminate in which the spacer 80 and/or the spacer-strip 81 is stacked onto the FPC-strip 35, the adhesive is formed or coated so as to overlap at least the ground layer 27 (e.g. a partial area or entire area of the ground layer 27) on the side of the second surface 24n of the dielectric layer 24 on the same side as the ground layer 27, and the adhesive is not formed or coated so as to overlap the signal line 25 on the side of the first surface 24m of the dielectric layer 24 on the same side as the signal line 25. In such an embodiment, the transmission characteristic of HF signal may be ensured which is equivalent to one obtained in a case where the FPC-strips 35 are not bundled by the bundling member 5 as depicted in FIG. 9. This is proved by a result of evaluation of prototypes based on actual measurements of FIGS. 10-13.

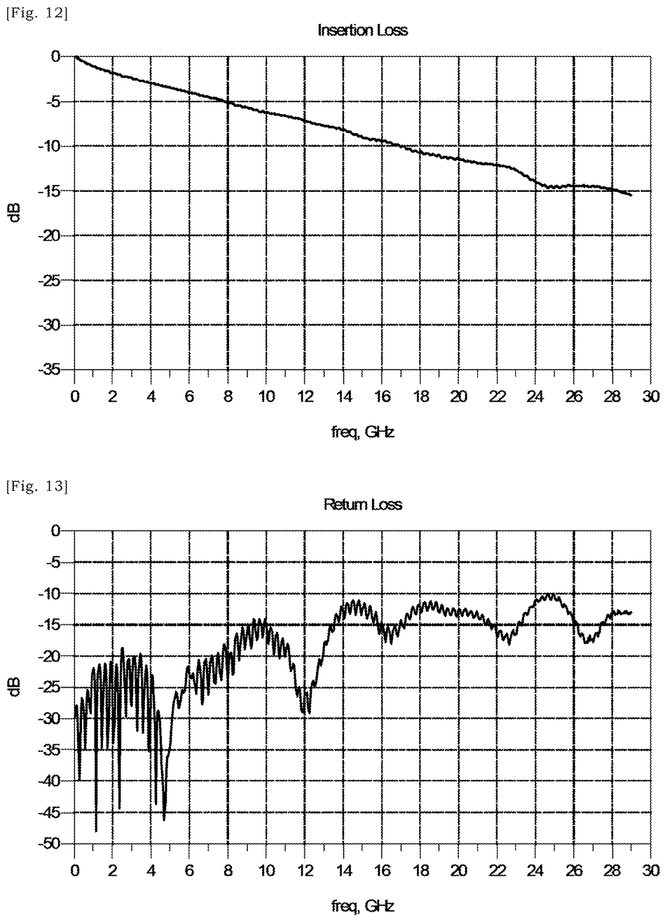

FIG. 10 is a chart showing fluctuation in insertion loss regarding frequency of the cable device 9 depicted in FIG. 1, and FIG. 11 is a chart showing fluctuation in return loss regarding the frequency of the cable device 9. FIG. 12 is a chart showing fluctuation in insertion loss regarding the embodiment depicted in FIG. 9 where the bundling member 5 is not used for bundling, and FIG. 13 is a chart showing fluctuation in return loss thereof. Insertion and return losses would increase when the FPC-strips 35 are bundled by the bundling member 5 but it would be observable that it is well suppressed by the use of the spacer 80.

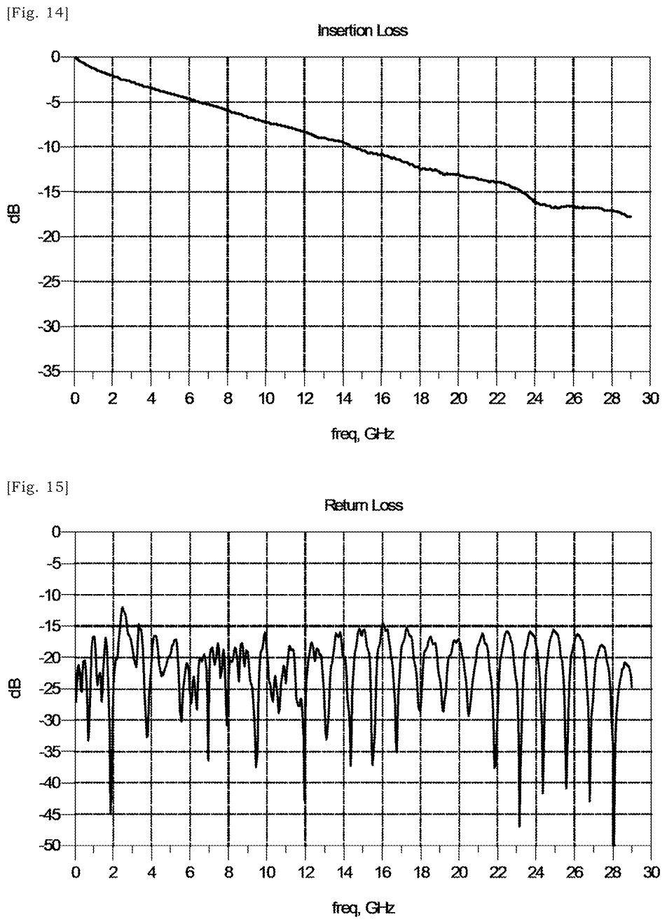

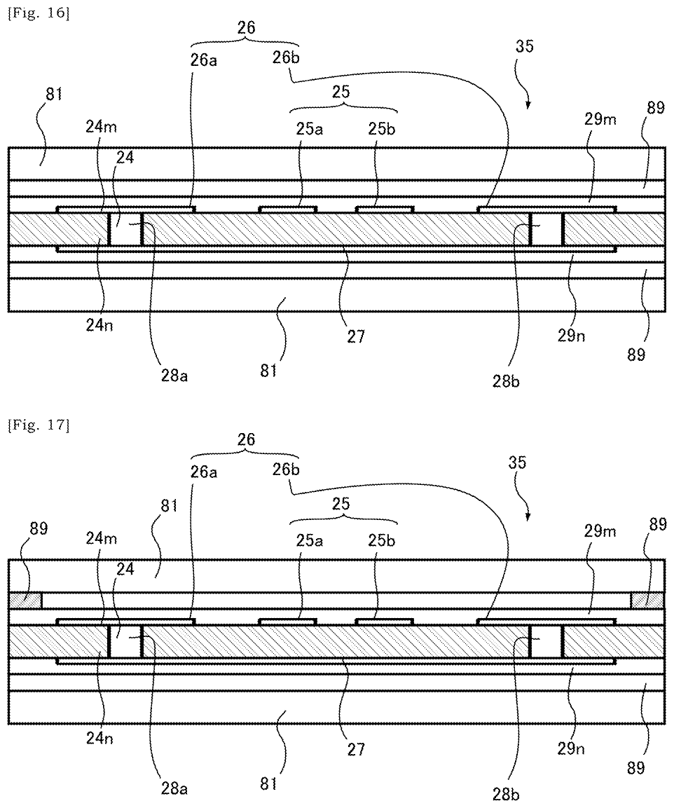

FIGS. 14 and 15 show results when the FPC-strips 35 are bundled by the bundling member 5 without using the spacer 80 (FIG. 14 concerns insertion loss; and FIG. 15 concerns return loss). Comparison of these figures with FIGS. 10 and 11 allows one to appreciate that the use of the spacer 80 as in the present disclosure is advantageous.

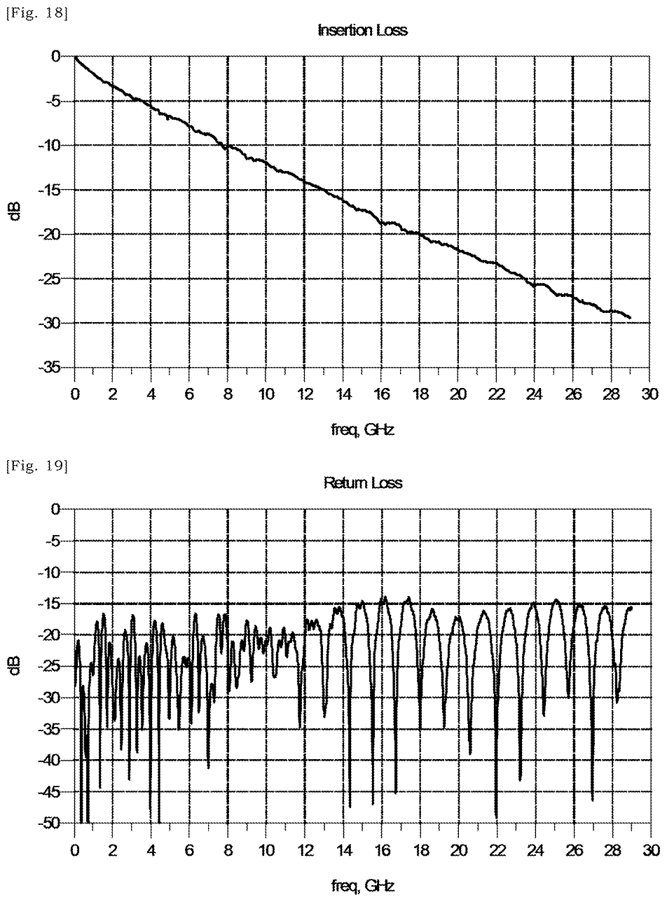

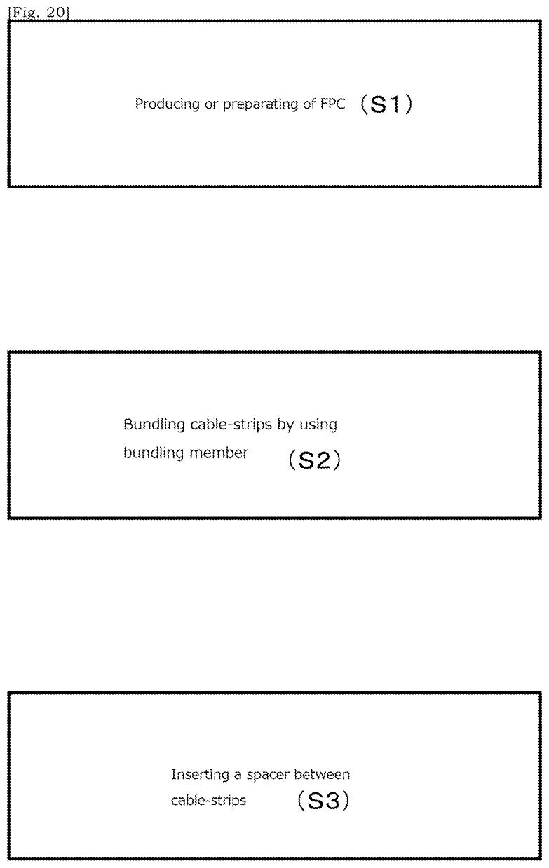

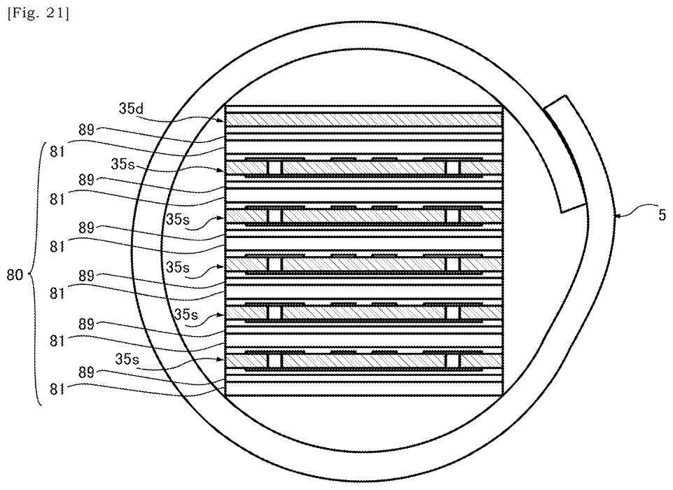

In some cases, the spacer-strips 81 are stacked onto the both sides of the FPC-strip 35 so as to sandwich the FPC-strip 35 as depicted in FIG. 16. In some cases, the adhesive is not formed so as to overlap the signal line 25 on the side of the first surface 24m of the dielectric layer 24 on the same side as the signal line 25 as depicted in FIG. 17, thus suppressing or avoiding the degradation of a transmission characteristic of HF signal in the cable device 9 due to the adhesive in the vicinity of the signal line 25. FIGS. 18 and 19 show results when the laminates of FIG. 16 are bundled by the bundling member 5 (FIG. 18 concerns insertion loss; and FIG. 19 concerns return loss). Note that, dependent to the material selected for the spacer, the spacer may be stacked onto the FPC through thermal compression bonding, heat welding, ultrasonic welding or the like without using the adhesive.

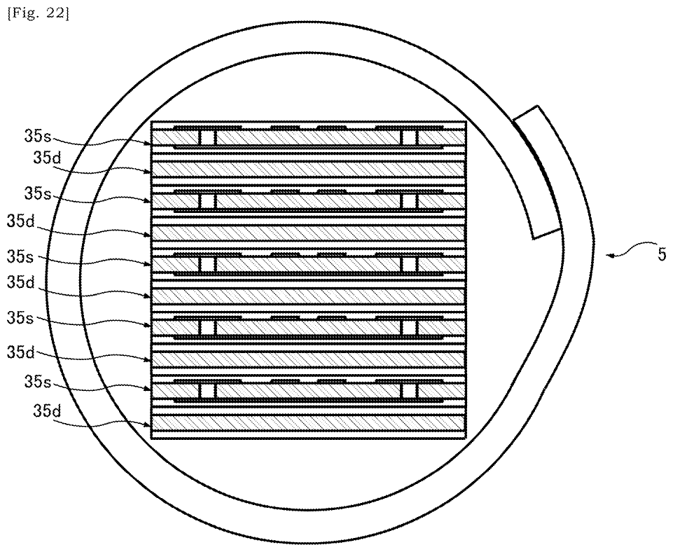

Method of producing the cable device 9 will be discussed with reference to FIG. 20. This production method includes producing or preparing a flexible cable (S1); bundling plural FPC-strips into a stacked state by using bundling member (S2); and inserting a spacer between the FPC-strips in the stacking direction of the FPC-strips (S3). This allows the effects equal to ones as discussed above. The preparing a flexible cable encompasses buying a flexible cable. The processes S2 and S3 may be performed by human manually or by machine.

If the spacer or the spacer-strips are stacked onto the FPC-strips in advance, the processes S2 and S3 would be performed simultaneously. That is, simultaneously as the FPC-strips 35 with the spacer or the spacer-strips are bundled into a stacked state by the bundling member 5, the spacer or the spacer-strip would be inserted between the FPC-strips 35. For this purpose, the above-noted production method may further include stacking the spacer or the spacer-strip onto the flexible cable. For a purpose of this stacking, an adhesive may be used; or thermal compression bonding, heat welding, ultrasonic welding or the like may be used. In some cases, the spacer and/or the spacer-strip is stacked selectively onto the side of the ground of the FPC.

For a purpose of improved efficiency of manufacturing or assembling, the above-noted production method may further include cutting the spacer, which has been stacked on to the flexible cable, at locations corresponding to slits to form plural spacer-strips. Cutting of the spacer may be performed by using a cutter, rotational blade or die.

As appreciated from FIG. 21, there is no need that every FPC-strip 35 is a signal transmission strip 35s including a HF signal transmission line. The FPC-strips 35 may include at least one dummy strip 35d additionally to the signal transmission strips 35s. The dummy strip 35d is a strip provided with no HF signal transmission line. Typically, the dummy strip 35d does not include a conductive layer (e.g. all of the signal line 25, the ground line 26, and the ground layer 27), and is made of dielectric material (e.g. a laminate of the dielectric layer 24, the first cover layer 29m, and the second cover layer 29n (e.g. a 3-layered laminate)). The spacer-strip 81 may be stacked onto the dummy strip 35d or this may be omitted.

The dummy strip 35d may be arranged at the outermost layer (see FIG. 21) in the stacking direction of the plural FPC-strips 35 in the bundling location by the bundling member 5 (e.g. the uppermost or lowermost layer if the stacking direction of the FPC-strips 35 is identical to the vertical direction). In such a configuration, the signal transmission strips are located away from other external apparatuses in accordance with an extent of thickness of the dummy strip 35d, allowing reduction in an extent of influence imparted to the HF signal transmission in the cable device 9 by electromagnetic waves emitted from other external apparatuses. Note that, the dummy strips 35d may be arranged at both of the outermost layers in the stacking direction of the plural FPC-strips 35 in the bundling location by the bundling member 5 (e.g. the uppermost and lowermost layers if the stacking direction of the FPC-strips 35 is identical to the vertical direction).

In a set of the FPC-strips 35 bundled by the bundling member 5, the number of the signal transmission strips 35s is preferably greater than the number of the dummy strips 35d, thus securing a required number of channels for signal transmission. Typically, in a set of the FPC-strips 35 bundled by the bundling member 5, the number of the dummy strips 35d is one or two and/or the number of the signal transmission strips 35s is two, three, four or more. In some cases, in the bundling location by the bundling member 5, the dummy strip 35d is adjacent to another FPC-strip 35 (e.g. signal transmission strip) but not interposed between other two FPC-strips 35.

The dummy strip 35d may be located on one end or both ends of the FPC 2 in its width direction when the FPC-strips 35 are not bundled by the bundling member 5 (e.g. in a state depicted in FIG. 2). In such a configuration, it would be possibly without error to identify the location of the dummy strip 35d, thus suppressing the confusion between the dummy strip 35d and the signal transmission strip 35s. Also, the dummy strips 35d would be more easily positioned at the outermost layer. Alternatively or additionally, the dummy strip 35d may be located in the vicinity of the center or closer to the center of the FPC 2 in its width direction. In this case either, the dummy strip 35d is more easily positioned at the outermost layer. In either way, for an identification purpose of the dummy and signal transmission strips 35d and 35s, a marker may be applied to one of them (e.g. the dummy strip 35d).

As depicted in FIG. 22, the dummy and signal transmission strips 35d and 35s may be alternately stacked whereby dummy strips 35d are used as a spacer (particularly, spacer-strips).

Based on the above disclosure, a skilled person would be able to add various modifications to the respective embodiments and respective features. Contacts may be formed in various manners other than the manners depicted in the drawings. As shown in FIG. 23, an embodiment is envisioned where the spacer 80 is a part of the bundling member 5; such embodiment is within the scope of the present claim 1. In FIG. 23, the bundling member 5 has plural fins 87 serving as the spacer 80, and the FPC-strips 35 can be inserted into the grooves between the fins 87.

### REFERENCE CODE

1: High-frequency signal transmission device

2: FPC

2a: First end

2b: Second end

5: Bundling member

7: Transmission line

9: Cable device

21: Slit

24: Dielectric layer

25: Signal line

26: Ground line

27: Ground layer

28: Through-electrode

29m: First cover layer

29n: Second cover layer

5: FPC-strip

35s: Signal transmission strip

35d: Dummy strip

80: Spacer

81: Spacer-strip

1. A cable device comprising:
a flexible cable including a plurality of cable-strips formed in accordance with one or more slits, the plurality of cable-strips including two or more signal transmission strips each of which includes at least one high-frequency signal transmission line;
one or more bundling members for bundling the plurality of cable-strips into a stacked state; and
a spacer interposed between the signal transmission strips in a stacking direction of the cable-strips in at least one or more bundling locations by the one or more bundling members.

2. The cable device of claim 1, wherein the high-frequency signal transmission line includes one or more signal lines formed on a first surface of a dielectric layer, and a ground layer formed on a second surface of the dielectric layer; and
the spacer is stacked onto the signal transmission strip on the side of the second surface on the same side as the ground layer.

3. The cable device of claim 2, wherein the spacer is stacked onto the signal transmission strip via an adhesive on the side of the second surface on the same side as the ground layer.

4. The cable device of claim 2 or 3, wherein the spacer is not stacked onto the signal transmission strip via an adhesive on the side of the first surface on the same side as the signal layer.

5. The cable device of claim 3, wherein the adhesive is formed to overlap at least the ground layer on the side of the second surface on the same side as the ground layer

6. The cable device of any one of claims 1-5, wherein the spacer includes one or more spacer-strips.

7. The cable device of claim 6, wherein the spacer-strips are stacked at least onto the signal transmission strips.

8. The cable device of claim 6 or 7, wherein the spacer includes two or more spacer-strips, and the signal transmission strip of single layer and the spacer-strip of single layer are alternately stacked in the stacking direction of the cable-strips in the one or more bundling locations.

9. The cable device of claim 7 or 8, wherein the slit formed in the flexible cable has a first slit end closer to a first end of the flexible cable and a second slit end closer to a second end of the flexible cable, and
a length of the spacer-strip is equal to or greater than a half of a length of the slit between the first and second slit ends.

10. The cable device of any one of claims 1-9, wherein a relative permittivity of the spacer is 2 or less; and/or a thickness of the spacer is 0.1 mm or more; and/or a material of the spacer is a non-woven fabric or cloth or paper.

11. The cable device of any one of claims 1-10, wherein the plurality of cable-strips includes at least one dummy strip in addition to the two or more signal transmission strips, the dummy strip including no high-frequency signal transmission line, and wherein
the at least one dummy strip is located at an outermost layer in the stacking direction of the plurality of cable-strips at least in the one or more bundling locations by the one or more bundling members.

12. The cable device of any one of claims 1-11, wherein each of the two or more signal transmission strips includes:
a dielectric layer;
one or more differential signal lines formed on a first surface of the dielectric layer;
at least a pair of ground lines formed on the first surface of the dielectric layer so as to sandwich the one or more differential signal lines at both sides thereof;
a ground layer formed on a second surface of the dielectric layer; and
at least a pair of through-electrodes that connect the respective ground lines of the at least a pair of ground lines to the ground layer.

13. The cable device of any one of claims 1-12, wherein the one or more bundling members each is a tubular member encapsulating a laminate including the cable-strips and the spacer.

14. The cable device of any one of claims 1-13, wherein the plurality of cable-strips are bundled by the bundling members for each subset of the plurality of cable-strips.

15. A method of producing a cable device, the method comprising:
producing or preparing a flexible cable including a plurality of cable-strips formed in accordance with one or more slits, the plurality of cable-strips including two or more signal transmission strips each of which includes at least one high-frequency signal transmission line;
bundling the plurality of cable-strips into a stacked state by one or more bundling members; and
inserting a spacer between the signal transmission strips in a stacking direction of the cable-strips at least in one or more bundling locations by the one or more bundling members.

16. The method of claim 15, further comprising stacking the spacer onto the flexible cable.

17. The method of claim 16, further comprising cutting the spacer, which has been stacked onto the flexible cable, at positions corresponding to the slits so as to form a plurality of spacer-strips.

18. The method of any one of claims 15-17, wherein the high-frequency signal transmission line includes one or more signal lines formed on a first surface of a dielectric layer, and a ground layer formed on a second surface of the dielectric layer; and
the spacer is stacked onto the signal transmission strip on the side of the second surface on the same side as the ground layer.

19. The method of claim 17, wherein the signal transmission strip of single layer and the spacer-strip of single layer are alternately stacked in the stacking direction of the cable-strips at least in one or more bundling locations by the one or more bundling members.

20. A cable device comprising:
a flexible cable including a plurality of cable-strips formed in accordance with one or more slits, the plurality of cable-strips including two or more signal transmission strips each of which includes at least one high-frequency signal transmission line; and
one or more spacer-strips which can be interposed between the signal transmission strips in a stacking direction of the cable-strips in one or more bundling locations where the plurality of cable-strips are bundled into a stacked state.
